(19) United States
(12) Patent Application Publication
(10) Pub. No.: US 2018/0206411 A1
(43) Pub. Date: Jul. 26, 2018

(54) LED FLIP CHIP PLANT GROW LIGHT

(71) Applicant: STARLIGHT LED INC., Milpitas, CA (US)

(72) Inventors: Pao Chen, Milpitas, CA (US); Sang Han, Fremont, CA (US)

(21) Appl. No.: 14/892,563

(22) PCT Filed: Oct. 14, 2015
(86) PCT No.: PCT/US2015/055570

§ 371 Date: Nov. 19, 2015

(51) Int. Cl. A01G 7/04; H01L 25/075; H01L 33/50; H01L 33/62; H01L 33/64; F21K 9/64; F21V 29/70; F21V 19/00

(52) U.S. Cl. CPC A01G 7/045; H01L 25/0753; H01L 33/502; H01L 33/62; F21Y 2115/10; F21K 9/64; F21V 29/70; F21V 19/0015; H01L 33/647

(57) ABSTRACT

Techniques for providing plant growth lights with improved performance and cost are discussed herein. Some embodiments may provide for a light emitting diode (LED) flip chip chip-on-board (COB) module for optimizing plant growth, including: a circuit board; ultraviolet (UV) LED flip chips connected to the circuit board; a royal-blue phosphor or fluorescent layer covering a first portion of the UV LED flip chips; and a deep-red phosphor or fluorescent layer covering a second portion of the UV LED flip chips. The royal-blue phosphor or fluorescent layer absorbs UV light generated by the first portion of the UV LED flip chips and converts the UV light into broad-band light in royal-blue spectrums. The a deep-red phosphor or fluorescent layer absorbs UV light generated by the second portion of the UV LED flip chips and converts the UV light into broad-band light in deep-red spectrums.

### CROSS-REFERENCE TO RELATED APPLICATION

The present application is a U.S. National Stage of International Application No. PCT/US2015/055570, filed Oct. 14, 2015, which is incorporated by reference in its entirety.

### TECHNICAL FIELD

The example embodiments of the present invention generally relate to techniques for providing light emitting diode devices, and more particularly to designs and fabrication processes of chip on board light emitting diode devices for optimized plant growth.

### BACKGROUND

Plant grow lights are designed to enhance or stimulate plant growth by photosynthesis through appropriate spectral radiation. Plant grow lights are generally applied while naturally occurring light is insufficient, such as due to high latitude location or seasonal changes. Today, plant grow lights also provide supplemental lighting for photosynthesis to accelerate plant growth or boost production of nutritious contents.

Based on the results of photosynthesis research, an ideal plant grow light should provide photonic energy covering two spectral regimes of 380 nm-490 nm and 600 nm-700 nm for Chlorophyll a (with absorption peaks at 430 nm and 662 nm (Deep Red)) and Chlorophyll b (with absorption peaks at 453 nm (Royal Blue) and 642 nm).

Conventional lighting modules for plant growth are structured similarly to the diagrams shown in FIGS. 1(a) and 1(b), respectively showing a top view and a side view of a conventional lighting module 100. The lighting source includes deep-red LED packages 102 and royal-blue LED Packages 104 that are mounted on the printed circuit board (PCB) 106 which consists of a dielectric substrate 108 and two independent circuits 110 and 122 respectively driving the deep-red LED packages 102 and the royal-blue LED packages 104.

FIG. 2 shows a structural diagram of an LED package 200, which is an example of a deep-red LED package 102 or a royal-blue LED package 104. The LED package 200 includes a LED chip 202 including an LED substrate 216, with its bottom surface bonded on the top surface of a dielectric base 204 via a bonding adhesive 212, two conductive channels 206 formed through the dielectric base 204 to form two bonding pads 208 and two contact pads 210 on the top and bottom surfaces of the dielectric base 204. Two bonding wires 218 connect the LED chip 202 and the bonding pads 208, and an optical dome/Lens 214 components on the top surface. The LED Package 200 is directly bonded onto the PCB (e.g., PCB 106) via the connection between contact pads 210 of LED package 200 and electrodes of the PCB.

The thermal energy generated by the LED chip 202 is dissipated to the dielectric base 204 through the LED substrate 216, which is made of inefficient thermal-conductive material, such as sapphire, SiC, and GaN, while the dielectric base 204 is made from non-thermal-conductive plastic. These applied material results in insufficient thermal dissipation and higher chip temperature. The consequence is then shorter LED lifetime, color change and less brightness. In order to improve thermal dissipation, some use ceramic material, such as AlN and Al2O3, to fabricate the dielectric base 204. However, ceramic is relatively expensive and not necessarily perform sufficient thermal conductivity.

Plant grow lights employing LED packages conventionally suffer from several other problems, such as insufficient spectrum coverage, shorter life span caused by weak thermal dissipation and high cost of the deep-red LED packages 102.

For example, FIG. 3(a) shows the emitting spectrum of royal-blue LED packages and deep-red LED packages with reference to the ideal spectrum coverage 306, i.e., 380 nm-490 nm and 600 nm-700 nm. Because LED Packages are semiconductor lighting source, their emitting spectrums 302 and 304 are considered monochrome, and the full width of half magnitude (FWHM) is typically around 25 nm-30 nm which is much narrower when compared to the ideal spectrum coverage 306.

To resolve narrow spectrum issue, conventional techniques include adding red LED packages into the module to extend the spectrum coverage between 600 nm and 700 nm, as shown in FIG. 3(b) by spectrum 310 of the red LED package. However, this method requires a larger module space and more LED Packages that result in higher manufacture cost, mostly because of the higher cost of the red LED packages and deep-red LED packages.

Furthermore, the red and deep-red LED packages are very sensitive to thermal conditions. When operating temperature increases, both lighting efficacy and life span are reduced, such as by a greater relative magnitude compared with the royal-blue LED packages.

### BRIEF SUMMARY

Various embodiments are directed to a LED flip chip chip-on-board (COB) module (or “LED COB module”) that is advantageous to conventional techniques employed for the plant lighting. The LED COB module is configured to overcome the obstacles that conventional plant grow lights are suffering from, such as (i) narrow emitting spectrum from LED Packages, (ii) strong thermal decay and short life span of red and deep-red LED packages, and (iii) high cost on red and deep-red LED packages.

Some embodiments may provide for a light emitting diode (LED) flip chip chip-on-board (COB) module (“LED module”) for optimizing plant growth, including: a circuit board; ultraviolet (UV) LED flip chips connected to the circuit board; a royal-blue phosphor or fluorescent dye layer covering a first portion of the UV LED flip chips; and a deep-red phosphor or fluorescent dye layer covering a second portion of the UV LED flip chips.

In some embodiments, the circuit board may include: a first circuit configured to control the first portion of the UV LED flip chips; and a second circuit configured to control the second portion of the UV LED flip chips.

In some embodiments, the circuit board may be a metal core printed circuit board including: a metal core substrate; and a dielectric layer on the metal core substrate, wherein the first circuit and the second circuit are each on the dielectric layer.

In some embodiments, a UV LED flip chip of the UV LED flip chips may include: an LED substrate; a first contact pad connected to the circuit board; a second contact pad connected to the circuit board; and a passivation layer between the first contact pad and the second contact pad. In some embodiments, the UV LED flip chip may further include a thermal pad positioned between and electronically isolated from the first contact and the second contact pad.

In some embodiments, the circuit board may be a pillar metal core printed circuit board including: a metal core substrate including a mesa projection; a dielectric layer on the metal core substrate; a first electrode pad on the dielectric layer; a second electrode pad on the dielectric layer. The mesa projection may extend from the metal core substrate, through the dielectric layer, and between the first and second electrode pads. The first contact pad of the UV LED flip chip may be connected to the first electrode pad. The second contact pad of the UV LED flip chip may be connected to the second electrode pad. The thermal pad of the UV LED flip chip may be thermally coupled to the mesa projection of the metal core substrate.

In some embodiments, the royal-blue phosphor or fluorescent dye layer may be formed by direct deposition of royal-blue phosphor or fluorescent dye, or made from an epoxy layer doped with royal-blue phosphor or fluorescent dye. The deep-red phosphor or fluorescent dye layer may be formed by direct deposition of deep-red phosphor or fluorescent dye, or made from an epoxy layer doped with deep-red phosphor or fluorescent dye.

In some embodiments, the royal-blue phosphor or fluorescent dye layer may absorb UV light generated by the first portion of the UV LED flip chips and convert the absorbed energy into broad-band spectrums covering wavelength between 380 nm and 490 nm. In some embodiments, the converted broad-band spectrums include at least a peak wavelength between 420 nm and 460 nm.

In some embodiments, the deep-red phosphor or fluorescent dye layer may absorb UV light generated by the second portion of the UV LED flip chips and convert the absorbed energy into broad-band spectrums covering wavelength between 600 nm and 700 nm. In some embodiments, the converted broad-band spectrums include at least a peak wavelength between 640 nm and 670 nm.

Some embodiments may provide for a method of optimizing plant growth, including: providing a light emitting diode (LED) flip chip chip-on-board (COB) module, including: ultraviolet (UV) LED flip chips connected to a circuit board; a royal-blue phosphor or fluorescent dye layer covering a first portion of the UV LED flip chips; a deep-red phosphor or fluorescent dye layer covering a second portion of the UV LED flip chips; and the circuit board, including: a first circuit configured to control the first portion of the UV LED flip chips; and a second circuit configured to control the second portion of the UV LED flip chips. The method may further include independently controlling the first portion of the UV LED flip chips and the second portion of the UV LED flip chips using the first circuit and second circuit, respectively.

In some embodiments, the method may further include, with the royal-blue phosphor or fluorescent dye layer, absorbing UV light generated by the first portion of the UV LED flip chips and converting the UV light into broad-band spectrums covering wavelength between 380 nm and 490 nm.

In some embodiments, the method may further include, with the deep-red phosphor or fluorescent layer, absorbing UV light generated by the second portion of the UV LED flip chips and converting the UV light into broad-band spectrums covering wavelength between 600 nm and 700 nm.

In some embodiments, independently controlling the first portion of the UV LED flip chips and the second portion of the UV LED flip chips includes adjusting an output intensity of the first portion of the UV LED flip chips with the first circuit.

In some embodiments, independently controlling the first portion of the UV LED flip chips and the second portion of the UV LED flip chips includes adjusting an output intensity of the second portion of the UV LED flip chips with the second circuit.

These characteristics as well as additional features, functions, and details are described below. Similarly, corresponding and additional embodiments are also described below.

### BRIEF DESCRIPTION OF THE DRAWING(S)

Having thus described the example embodiments of the present invention in general terms, reference will now be made to the accompanying drawings, which are not necessarily drawn to scale, and wherein:

FIGS. 1(a) and 1(b), respectively, show a top view and a side view of a conventional lighting module;

FIG. 2 shows a structural diagram of a conventional LED package of a lighting module;

FIG. 3(a) shows the emitting spectrum of royal-blue LED packages and deep-red LED packages of the conventional lighting module along with ideal plant grow spectrums;

FIG. 3(b) shows the emitting spectrum of royal-blue LED packages, deep-red LED packages, and red LED packages of the conventional lighting module along with ideal plant grow spectrums;

FIGS. 4(a) and 4(b) respectively show top-view and side-view structural diagrams of an example of a LED flip chip chip-on-board (COB) module in accordance with some embodiments;

FIG. 5 shows a structural diagram of an example of a LED flip chip in accordance with some embodiments;

FIGS. 6 and 7 each shows an example of two converting spectral regimes of UV-excited deep-red phosphor and UV-excited royal-blue fluorescent dye;

FIG. 8 shows an example of a LED flip chip COB module in accordance with some embodiments;

FIG. 9 shows a side-view of an example of a LED flip chip COB module in accordance with some embodiments;

FIG. 10 shows a top view of an example of a LED flip chip COB module in accordance with some embodiments;

FIG. 11 shows the emitting and converting spectrums of royal-blue LED flip chips and deep-red phosphor or fluorescent dye, respectively, in accordance with some embodiments;

FIG. 12 shows a top view of an example of a LED COB module in accordance with some embodiments; and

FIG. 13 shows an example of a method for providing plant growth lighting with an LED COB module in accordance with some embodiments.

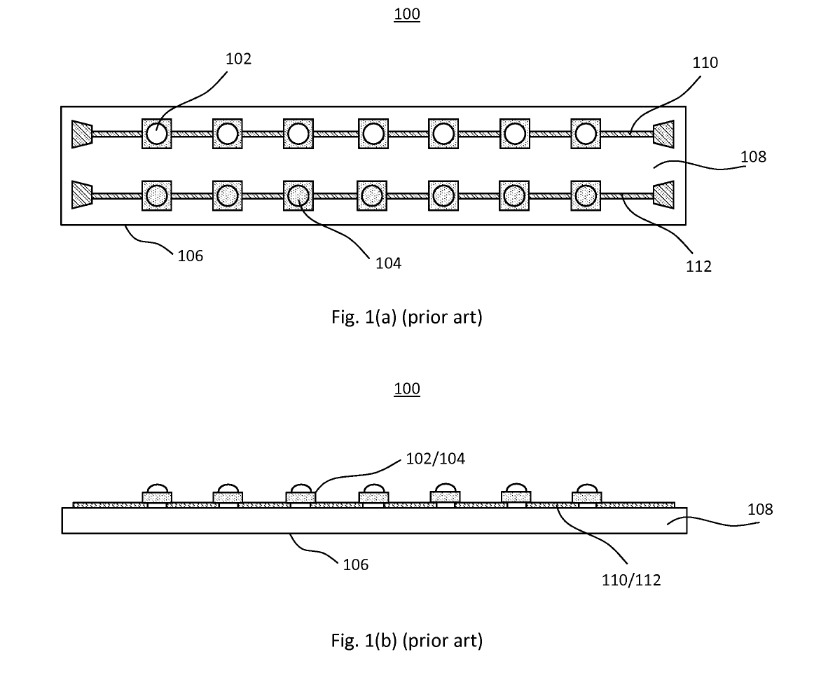

### DETAILED DESCRIPTION

Various embodiments will now be described more fully with reference to the accompanying drawings, in which some, but not all embodiments of the disclosure are shown. This disclosure may be embodied in many different forms and should not be construed as limited to the embodiments set forth; rather, these example embodiments are provided so that this disclosure will be thorough and complete, and will fully convey the scope of the disclosure to those skilled in the art. Like numbers refer to like elements throughout.

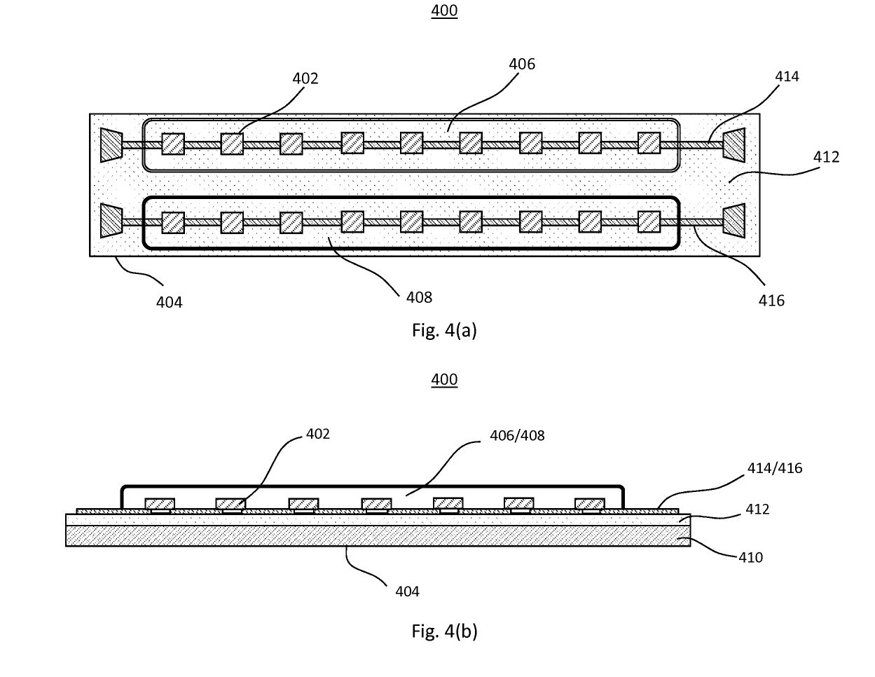

FIGS. 4(a) and 4(b) respectively show top-view and side-view structural diagrams of an LED COB module 400, in accordance with some embodiments. Instead of employing royal-blue and/or deep-red LED packages, the LED COB module 400 may include ultraviolet (UV) LED flip chips 402 bonded on a Metal Core Printed Circuit Board (MCPCB) 404, and two separate phosphor or fluorescent dye layers 406 and 408. The phosphor or fluorescent dye layer may be a direct coating of phosphor or fluorescent dye, or an epoxy layer doped with phosphor or fluorescent dye. The MCPCB 404 may include a metal core substrate 410, a dielectric layer 412 on the top of metal core substrate 410, and two independent circuits 414 and 416 on the top of the dielectric layer 412. The two circuits 414 and 416 divide the UV LED flip chips 402 into two groups, and enable independent driving-current controls over two groups of UV LED flip chips 402. One group of UV LED flip chips 402 may be covered by the royal-blue phosphor or fluorescent dye layer 406, and the other may be covered by the deep-red phosphor or fluorescent dye layer 408. Those phosphors and fluorescent dye layers are able to absorb UV photons generated by the UV LED flip chips 402 and then convert the absorbed energy into broad-band light in royal-blue and deep-red spectrums.

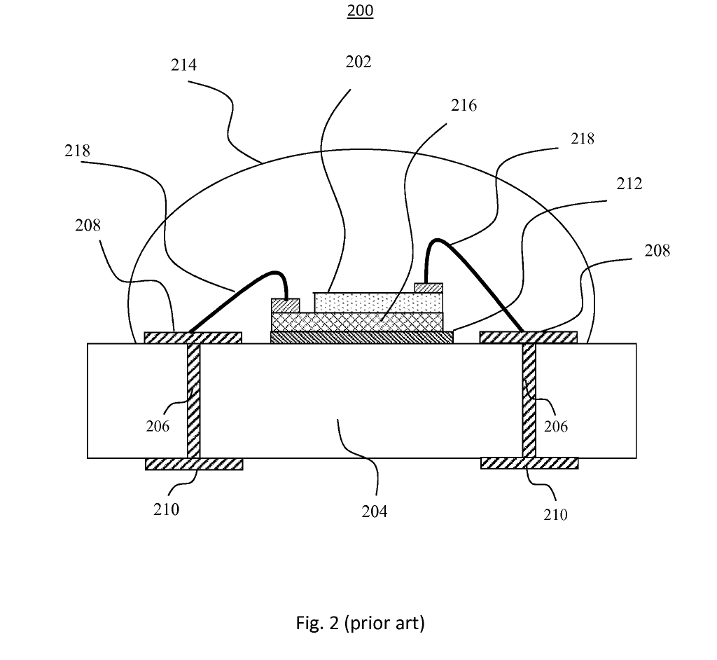

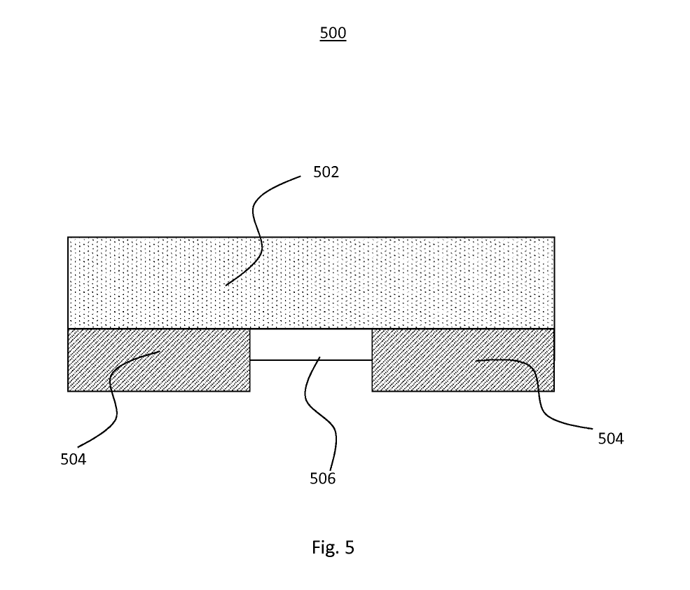

FIG. 5 shows a structural diagram of an example of an (e.g., UV) LED flip chip 500, in accordance with some embodiments. The LED flip chip 500 is an example of a 2 pad flip chip, and may include an LED substrate 502, two contact pads 504 and a passivation layer 506 between the two contact pads 504 to provide electrical isolation between the two contact pads 704. The LED flip chip 500 may be directly bonded on the PCB/MCPCB (e.g., MCPCB 404 shown in FIG. 4). While the functionality of the LED flip chip 500 may be similar to an LED Package when integrated on the PCB/MCPCB (e.g., light emission), the LED flip chip 500 is much simpler than the LED package, and much smaller without other components such as the dielectric base 204, bonding wires 218, bonding pads 208, and lens 214 as shown in FIG. 2 for the LED package 200. In addition, the thermal resistance of flip chip 500 is less than that of LED package due to less thermal resistant material between LED junction and the PCB/MCPCB.

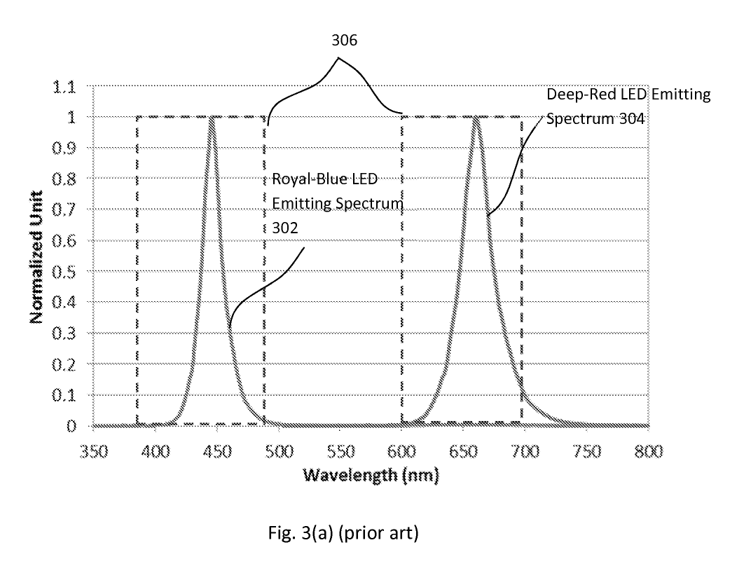

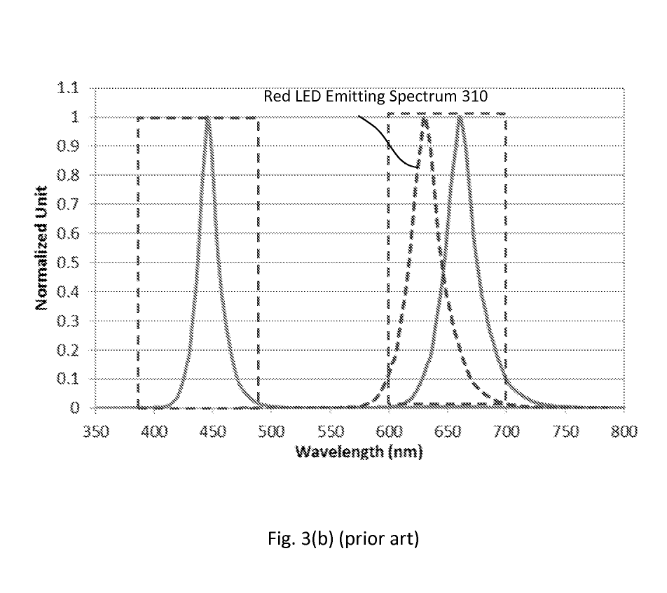

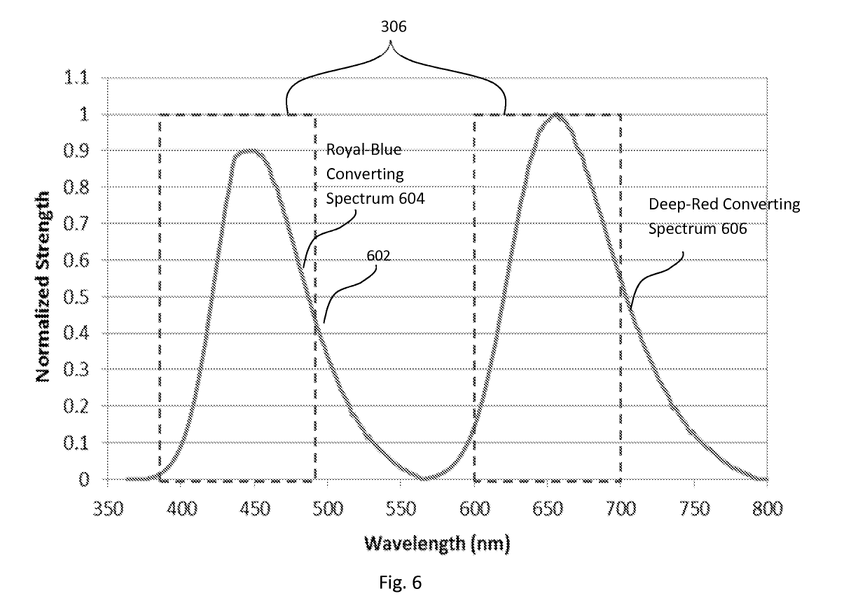

FIG. 6 shows an example of two converting spectral regimes of UV-excited deep-red phosphor and UV-excited royal-blue fluorescent dye with peak wavelength at 660 nm and 448 nm, respectively. Compared to the monochrome LED Packages spectrums (e.g., 302 and 304 as shown in FIG. 3(a)), the converting spectrum 602 of phosphor and fluorescent dye is broader, i.e., the FWHM is larger, and closer to the full coverage of the ideal spectrum 306 coverage for plant growth of 380 nm-490 nm and 600 nm-700 nm for Chlorophyll a and Chlorophyll b. The spectrum peaks of emitted light may correspond with the absorption peaks for Chlorophyll a at 430 nm and 662 nm and Chlorophyll b at 453 nm and 642 nm, such as by having a first spectral peak (e.g., the royal blue converting spectrum 604) between 420 nm and 460 nm and the second spectral peak (e.g., the deep-red converting spectrum 606) between 640 nm and 670 nm.

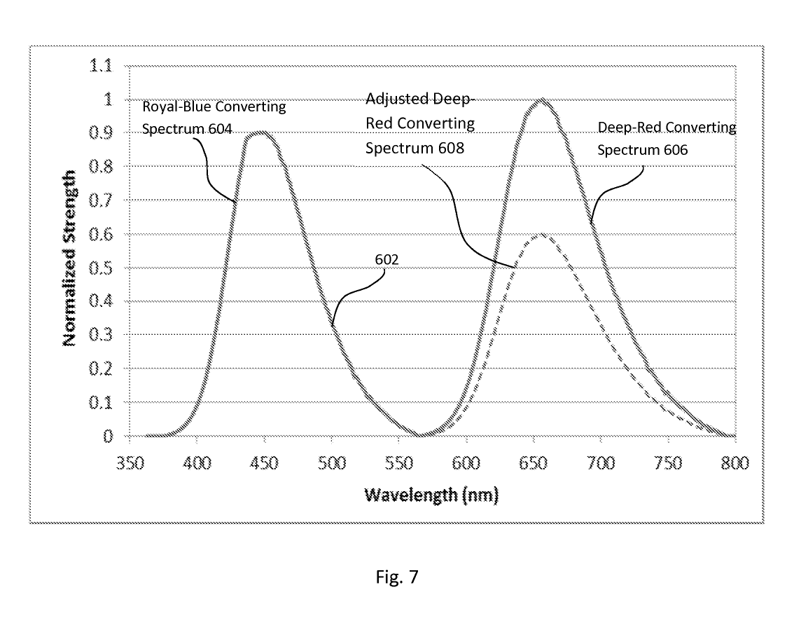

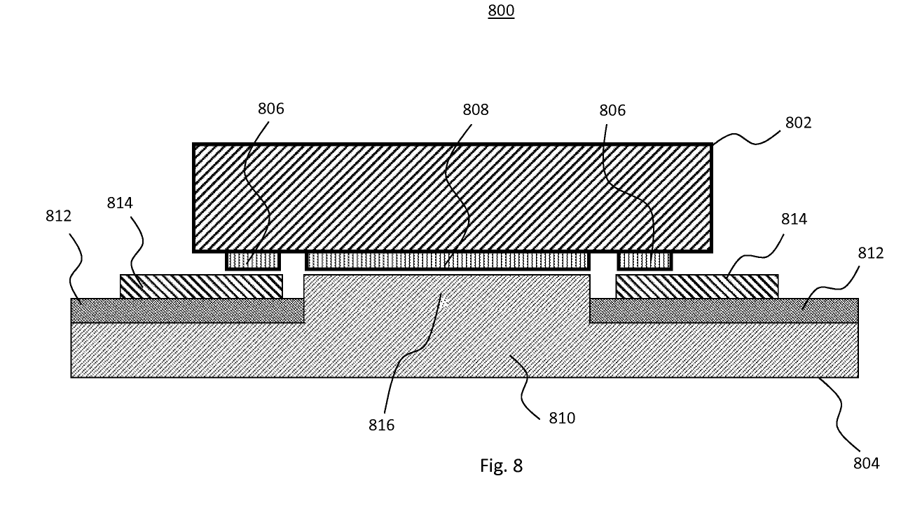

In some embodiments, the independent circuits 414 and 416 may enable the brightness adjustment of individual spectrums 604 and 606 upon the plant growth conditions. With reference to FIG. 7, for example, the deep-red spectrum 606 may be converted to the adjusted deep-red converting spectrum 608. Advantageously, deep-red light can be tuned for flowering plants, and in contrast, royal-blue light can be tuned to optimize plant growth rate and size.

Advantageously, less material cost can be achieved by replacing the conventional red and deep-red LED packages of conventional plant lights with a combination of UV LED flip chips and the deep-red phosphor or fluorescent dye layer over the UV LED flip chips. The LED COB module may also exhibit better thermal dissipation because of smaller thermal resistance. For example, LED Packages typically have 5 times larger thermal resistance than the LED COB module. As a result, issues related to thermal decay and shortened life span are prevented because of the good thermal dissipation, and without the use of costly red or deep-red LED packages.

In some embodiments, in order to further reduce the thermal resistance, the structures of LED COB module may be designed as discussed in U.S. Pat. No. 9,006,005, titled “Flip Light Emitting Diode Chip and Method of Fabricating the Same,” issued Apr. 14, 2015, which is incorporated by reference herein in its entirety.

FIG. 8 shows an example of a LED flip chip COB module 800, in accordance with some embodiments. The LED COB module 800 may include (e.g., multiple) UV LED flip chip 802 connected with a MCPCB 804. The UV LED flip chip 802 may be a 3-Pad flip chip, including two contact pads (e.g., N− and P− Pads) 806, and a thermal pad 808 positioned between but electrically isolated from two contact pads 806. The Pillar MCPCB 804 may include of a metal core substrate 810, a dielectric layer 812 on the top of the metal core substrate 810, two electrode pads 814 on the top of the dielectric layer 812, and a mesa projection 816 extended from the metal core substrate 810 and passing through the dielectric layer 812 to be positioned between the two electrode pads 806 but electrically isolated from them.

The two contact pads 806 of 3-Pad LED flip chip 802 are electrically connected to the two electrode pads 814 of the Pillar MCPCB 804, and the thermal pad 808 of the 3-Pad LED flip chip 802 is coupled to (e.g., thermally coupled, such as based on contact) the mesa projection 816 of the Pillar MCPCB 804. Advantageously, the LED COB module 800 is capable exhibiting lower thermal resistance.

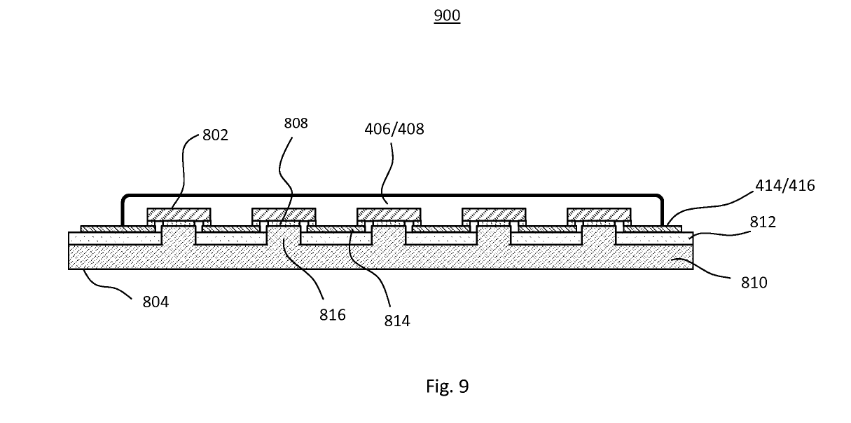

FIG. 9 shows a side-view of an example of a LED flip chip COB module 900, in accordance with some embodiments. Here, multiple 3-pad UV LED Flip Chips 802 are connected with the MCPCB 804 that includes mesa projections 816 to couple with the thermal pads 808 of the UV LED flip chips 802.

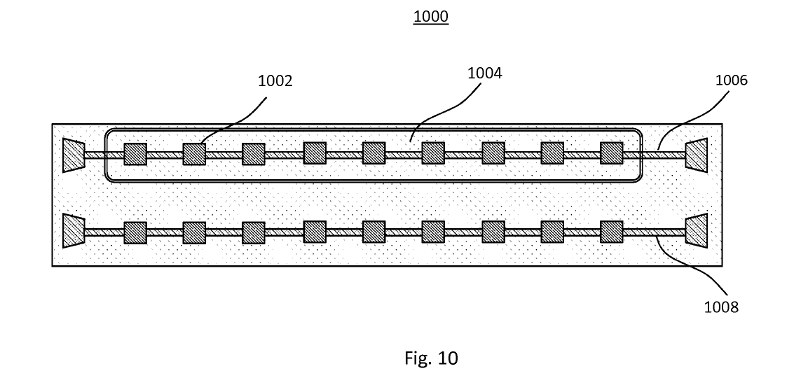

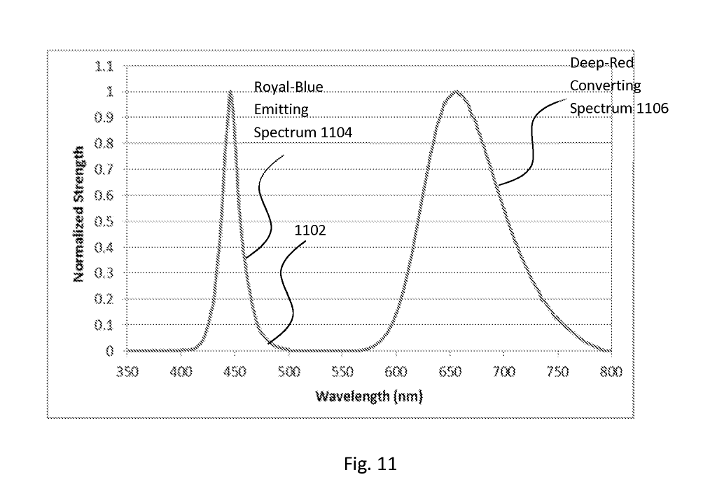

FIG. 10 shows a top view of an example of a LED flip chip COB module 1000, in accordance with some embodiments. Rather the using UV LED flip chips, the LED COB module 1000 includes royal-blue LED flip chips 1002 which emits light with peak between 445 nm and 460 nm. One group of the royal-blue LED flip chips 1002 (e.g., as defined by circuit trace connections of the circuit trace 1006) may be covered by a deep-red phosphor or fluorescent dye layer 1004, and the other group of the royal-blue LED flip chips 1002 (e.g., as defined by circuit trace connections of the circuit trace 1008) isn't covered by any phosphor or fluorescent dye. In this arrangement, the deep-red phosphor or fluorescent dye layer 1004 is able to absorb royal-blue photons and convert the absorbed energy into broad deep-red light, whereas the uncovered (or covered by a optically benign layer) group of royal-blue LED flip chips 1002 emit relatively narrower royal-blue spectrum, as shown in FIG. 11. For example, the spectrum 1102 of the LED COB module 1000 may include the royal-blue emitting spectrum 1104 and the deep-red converting spectrum 1106.

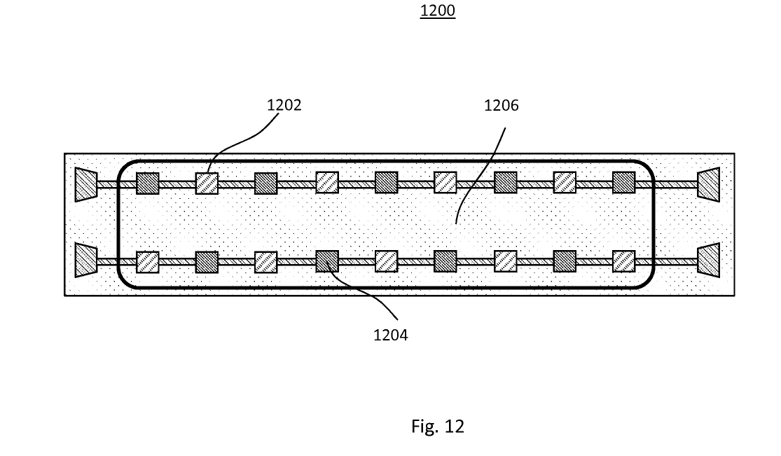

FIG. 12 shows a top view of an example of a LED COB module 1200, in accordance with some embodiments. The LED COB module 1200 may include multiple flip chip types, such as including a mixture of UV LED flip chips 1202 and royal-blue LED flip chips 1204. The UV and royal blue LED flip chips 1102 and 1104 may be covered by a phosphor or fluorescent dye layer 1206. The phosphor or fluorescent dye layer 1206 only converts UV light into deep-red light with broad spectrum, but behaves as a transparent layer to the royal-blue light. In this arrangement, the spectrum lighting performance is similar to the diagram shown in FIG. 11.

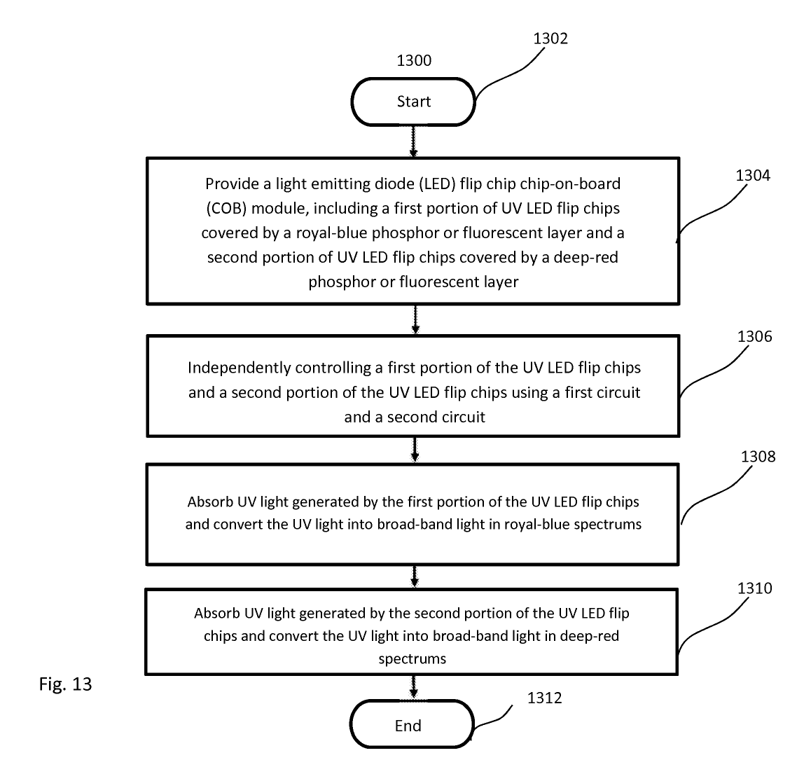

FIG. 13 shows an example of a method 1300 for providing plant growth lighting with an LED COB module, in accordance with some embodiments. Method 1300 may begin at 1302 and proceed to 1304, where a light emitting diode (LED) flip chip chip-on-board (COB) module may be provided. For the LED module including UV LED flip chips, providing the module may include fabricating the LED module, such as by fabricating the circuit board (e.g., the metal core printed circuit board), fabricating each of the UV LED flip chips, connecting the UV LED flip chips to the circuit board, and then disposing the royal-blue phosphor or fluorescent dye layer and the deep-red phosphor or fluorescent dye layer on the UV LED flip chips. The royal-blue phosphor or fluorescent dye layer may cover a first portion of the UV LED flip chips, and the deep-red phosphor or fluorescent dye layer may cover a second portion of the UV LED flip chips, as described above.

At 1306, the first portion of the UV LED flip chips and the second portion of the UV LED flip chips may be independently controlled to generate UV light at different intensities. For example, a first circuit of the circuit board may be configured to control the first portion of the UV LED flip chips and a second, independent circuit of the circuit board may be configured to control the second portion of the UV LED flip chips. As such, intensities of the flip chip groups may be adjusted independently to optimally stimulate plant growth in different types of plant.

At 1308, the royal-blue phosphor or fluorescent dye layer may be configured to absorb UV light generated by the first portion of the UV LED flip chips and convert the UV light into broad-band light in royal-blue spectrums. At 1310, the deep-red phosphor or fluorescent dye layer may be configured to absorb UV light generated by the second portion of the UV LED flip chips and convert the UV light into broad-band light in deep-red spectrums. It is appreciated that steps 1310 and 1312 may be different for other embodiments of the LED module, such as those that using different LED flip chip module types or phosphor/dye layers. Method 1300 may then proceed to 1312 and end.

Many modifications and other example embodiments set forth herein will come to mind to one skilled in the art to which these example embodiments pertain having the benefit of the teachings presented in the foregoing descriptions and the associated drawings. For example, the techniques discussed herein optimize light emission based on an ideal spectrum for plant growth. However, plants may have varying requirements or light optimization intensities (e.g., for various frequencies), and an LED flip chip COB module may be designed to accordingly. Therefore, it is to be understood that the embodiments are not to be limited to the specific ones disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions other than those explicitly described above are also contemplated as may be set forth in some of the appended claims. Although specific terms are employed herein, they are used in a generic and descriptive sense only and not for purposes of limitation.

For the avoidance of doubt, the present invention includes the subject matter as defined in the following numbered paragraphs (abbreviated “para.”).

Para 1. A light emitting diode (LED) flip chip chip-on-board (COB) module (“LED module”) for optimizing plant growth, comprising:
a circuit board;
royal-blue LED flip chips connected to the circuit board; and
a deep-red phosphor or fluorescent dye layer covering a portion of the royal-blue LED flip chips.

Para 2. The LED module of Para 1, wherein the circuit board includes:
a first circuit configured to control the first portion of the royal-blue LED flip chips; and
a second circuit configured to control the second portion of the royal-blue LED flip chips covered by the deep-red phosphor or fluorescent dye layer.

Para 3. The LED module of Para 2, wherein the circuit board is a metal core printed circuit board including:
a metal core substrate; and
a dielectric layer on the metal core substrate, wherein the first circuit and the second circuit are each on the dielectric layer.

Para 4. The LED module of Para 1, wherein a royal-blue LED flip chip of the royal-blue LED flip chips includes:
an LED substrate;
a first contact pad connected to the circuit board;
a second contact pad connected to the circuit board; and
a passivation layer between the first contact pad and the second contact pad.

Para 5. The LED module of Para 4, wherein the royal-blue LED flip chip further includes a thermal pad positioned between and electronically isolated from the first contact and the second contact pad.

Para 6. The LED module of Para 1, wherein:
the circuit board is a pillar metal core printed circuit board including:
   a metal core substrate including a mesa projection;
   a dielectric layer on the metal core substrate;
   a first electrode pad on the dielectric layer;
   a second electrode pad on the dielectric layer, wherein the mesa projection extends from the metal core substrate, through the dielectric layer, and between the first and second electrode pads; and
the first contact pad of the royal-blue LED flip chip is connected to the first electrode pad;
the second contact pad of the royal-blue LED flip chip is connected to the second electrode pad; and
the thermal pad of the royal-blue LED flip chip is thermally coupled to the mesa projection of the metal core substrate.

Para 7. The LED module of Para 1, wherein a deep-red phosphor or fluorescent dye layer is formed by direct deposition of deep-red phosphor or fluorescent dye, or made from an epoxy layer doped with deep-red phosphor or fluorescent dye.

Para 8. The LED module of Para 1, wherein the royal-blue LED flip chips emit spectrums with a peak wavelength between 440 nm and 465 nm, and a full width of half magnitude less than 30 nm.

Para 9. The LED module of Para 1, wherein the a deep-red phosphor or fluorescent dye layer absorbs royal-blue light generated by the second portion of the royal-blue LED flip chips and converts the absorbed energy into broad-band spectrums covering wavelength between 600 nm and 700 nm.

Para 10. The LED module of Para 9, wherein the converted broad-band spectrums include at least a peak wavelength between 640 nm and 670 nm.

Para 11. A light emitting diode (LED) flip chip chip-on-board (COB) module (“LED module”) for optimizing plant growth, comprising:
a circuit board;
royal-blue LED flip chips connected to the circuit board;
violet (UV) LED flip chips connected to the circuit board; and
a deep-red phosphor or fluorescent dye layer covering the UV LED flip chips and the royal blue LED flip chips.

Para 12. The LED module of Para 11, wherein the circuit board includes:
a first circuit configured to control the UV LED flip chips; and
a second circuit configured to control the royal-blue LED flip chips.

Para 13. The LED module of Para 12, wherein the circuit board is a metal core printed circuit board including:
a metal core substrate; and
a dielectric layer on the metal core substrate, wherein the first circuit and the second circuit are each on the dielectric layer.

Para 14. The LED module of Para 11, wherein a UV LED flip chip and a royal-blue LED flip chip of the UV LED flip chips and royal blue LED flip chips, respectively, includes:
an LED substrate;
a first contact pad connected to the circuit board;
a second contact pad connected to the circuit board; and
a passivation layer between the first contact pad and the second contact pad.

Para 15. The LED module of Para 14, wherein the UV LED flip chip and the royal-blue LED flip chip further includes a thermal pad positioned between and electronically isolated from the first contact and the second contact pad

Para 16. The LED module of Para 14, wherein:
the circuit board is a pillar metal core printed circuit board including:
   a metal core substrate including a mesa projection;
   a dielectric layer on the metal core substrate;
   a first electrode pad on the dielectric layer;
   a second electrode pad on the dielectric layer, wherein the mesa projection extends from the metal core substrate, through the dielectric layer, and between the first and second electrode pads; and
the first contact pad of the LED flip chip is connected to the first electrode pad;
the second contact pad of the LED flip chip is connected to the second electrode pad; and
the thermal pad of the LED flip chip is thermally coupled to the mesa projection of the metal core substrate.

Para 17. The LED module of Para 11, wherein a deep-red phosphor or fluorescent dye layer is formed by direct deposition of the deep-red phosphor or fluorescent dye, or made from an epoxy layer doped with deep-red phosphor or fluorescent dye.

Para 18. The LED module of Para 11, wherein the royal-blue LED flip chips emit spectrums with a peak wavelength between 440 nm and 465 nm, and a full width of half magnitude less than 30 nm.

Para 19. The LED module of Para 11, wherein the a deep-red phosphor or fluorescent dye layer absorbs UV light generated by the UV LED flip chips and converts the absorbed energy into broad-band spectrums covering wavelength between 600 nm and 700 nm.

Para 20. The LED module of Para 11, wherein the converted broad-band spectrums include at least a peak wavelength between 640 nm and 670 nm.

That which is claimed:

1. A light emitting diode (LED) flip chip chip-on-board (COB) module (“LED module”) for optimizing plant growth, comprising:
a circuit board;
ultraviolet (UV) LED flip chips connected to the circuit board;
a royal-blue phosphor or fluorescent dye layer covering a first portion of the UV LED flip chips; and
a deep-red phosphor or fluorescent dye layer covering a second portion of the UV LED flip chips.

2. The LED module of claim 1, wherein the circuit board includes:
a first circuit configured to control the first portion of the UV LED flip chips; and
a second circuit configured to control the second portion of the UV LED flip chips.

3. The LED module of claim 2, wherein the circuit board is a metal core printed circuit board including:
a metal core substrate; and
a dielectric layer on the metal core substrate, wherein the first circuit and the second circuit are each on the dielectric layer.

4. The LED module of claim 1, wherein a UV LED flip chip of the UV LED flip chips includes:
an LED substrate;
a first contact pad connected to the circuit board;
a second contact pad connected to the circuit board; and
a passivation layer between the first contact pad and the second contact pad.

5. The LED module of claim 4, wherein the UV LED flip chip further includes a thermal pad positioned between and electronically isolated from the first contact and the second contact pad.

6. The LED module of claim 5, wherein:
the circuit board is a pillar metal core printed circuit board including:
a metal core substrate including a mesa projection;
a dielectric layer on the metal core substrate;
a first electrode pad on the dielectric layer;
a second electrode pad on the dielectric layer, wherein the mesa projection extends from the metal core substrate, through the dielectric layer, and between the first and second electrode pads; and
the first contact pad of the UV LED flip chip is connected to the first electrode pad;
the second contact pad of the UV LED flip chip is connected to the second electrode pad; and
the thermal pad of the UV LED flip chip is thermally coupled to the mesa projection of the metal core substrate.

7. The LED module of claim 1, wherein the royal-blue phosphor or fluorescent dye layer is formed by direct deposition of royal-blue phosphor or fluorescent dye, or made from an epoxy layer doped with royal-blue phosphor or fluorescent dye.

8. The LED module of claim 1, wherein the deep-red phosphor or fluorescent dye layer is formed by direct deposition of deep-red phosphor or fluorescent dye, or made from an epoxy layer doped with deep-red phosphor or fluorescent dye

9. The LED module of claim 1, wherein the royal-blue phosphor or fluorescent dye layer absorbs UV light generated by the first portion of the UV LED flip chips and converts the absorbed energy into broad-band spectrums covering wavelength between 380 nm and 490 nm.

10. The LED module of claim 9, wherein the converted broad-band spectrums include at least a peak wavelength between 420 nm and 460 nm.

11. The LED module of claim 1, wherein the deep-red phosphor or fluorescent dye layer absorbs UV light generated by the second portion of the UV LED flip chips and converts the absorbed energy into broad-band spectrums covering wavelength between 600 nm and 700 nm.

12. The LED module of claim 11, wherein the converted broad-band spectrums include at least a peak wavelength between 640 nm and 670 nm.

13. A method for optimizing plant growth, comprising:
providing a light emitting diode (LED) flip chip chip-on-board (COB) module, including:
ultraviolet (UV) LED flip chips connected to a circuit board;
a royal-blue phosphor or fluorescent dye layer covering a first portion of the UV LED flip chips;
a deep-red phosphor or fluorescent dye layer covering a second portion of the UV LED flip chips; and
the circuit board, including:
a first circuit configured to control the first portion of the UV LED flip chips; and
a second circuit configured to control the second portion of the UV LED flip chips; and
independently controlling the first portion of the UV LED flip chips and the second portion of the UV LED flip chips using the first circuit and second circuit, respectively.

14. The method of claim 13 further comprising, with the royal-blue phosphor or fluorescent dye layer, absorbing UV light generated by the first portion of the UV LED flip chips and converting the UV light into broad-band spectrums covering wavelength between 380 nm and 490 nm.

15. The method of claim 14 further comprising, with the deep-red phosphor or fluorescent layer, absorbing UV light generated by the second portion of the UV LED flip chips and converting the UV light into broad-band spectrums covering wavelength between 600 nm and 700 nm.

16. The method of claim 14, wherein independently controlling the first portion of the UV LED flip chips and the second portion of the UV LED flip chips includes adjusting an output intensity of the first portion of the UV LED flip chips with the first circuit.

17. The method of claim 14, wherein independently controlling the first portion of the UV LED flip chips and the second portion of the UV LED flip chips includes adjusting an output intensity of the second portion of the UV LED flip chips with the second circuit.
